(19) United States
(12) Patent Application Publication
(10) Pub. No.: US 2012/0038022 A1
(43) Pub. Date: Feb. 16, 2012

(54) INSULATING SUBSTRATE FOR SEMICONDUCTOR DEVICE, AND SEMICONDUCTOR DEVICE

(75) Inventors: Kazuhide Tomiyasu, Osaka (JP); Yutaka Takafuji, Osaka (JP); Yasumori Fukushima, Osaka (JP); Kazuo Nakagawa, Osaka (JP); Kenshi Tada, Osaka (JP); Michiko Takei, Osaka (JP); Shin Matsumoto, Osaka (JP)

(73) Assignee: SHARP KABUSHIKI KAISHA, Osaka (JP)

(21) Appl. No.: 13/259,076

(22) PCT Filed: Oct. 26, 2009
(86) PCT No.: PCT/JP2009/068342

§ 371 Date: Oct. 18, 2011

(30) Foreign Application Priority Data
Mar. 25, 2009 (JP) 2009-074752

(51) Int. Cl. H01L 29/02; B32B 3/00

(52) U.S. Cl. 257/506; 428/141; 257/E29.002

(57) ABSTRACT

Disclosed is a glass substrate (20) that is capable of constituting a semiconductor device (10) when a monocrystalline silicon thin film (90) is provided on the surface of the substrate by transfer. The surface of the glass substrate (20) has a receiving surface (22) onto which the monocrystalline silicon thin film (90) can be provided. The height of the ripples on the receiving surface (22) having a period of 200 to 500 microns is no more than 0.40 nm.

### TECHNICAL FIELD

The present invention relates mainly to an insulating substrate for semiconductor device with a semiconductor layer provided thereon, and also to a semiconductor device having such an insulating substrate. More particularly, the present invention relates to a semiconductor device having a substrate such as a glass substrate on which a silicon monocrystalline film or the like is formed through the transfer of a silicon monocrystalline piece, a semiconductor piece, a semiconductor device, and the like, and also relates to an insulating substrate for use in such a semiconductor device.

### BACKGROUND ART

Conventionally, the integrated circuit device technology, with which a monocrystalline silicon substrate is processed to form several hundred millions of transistors thereon, and the thin film transistor (TFT) technology, with which a polycrystalline semiconductor film such as a silicon film is formed on a light-transmissive non-crystalline material such as a glass substrate and is processed to form transistors for making pixels, switching elements, and drivers of liquid crystal display devices, were proposed and have dramatically advanced while liquid crystal display devices, among other things, became widespread.

Integrated Circuit Device Technology

The integrated circuit device technology, one of the technologies mentioned above, allows formation of a large number of transistors on a commercially available monocrystalline silicon wafer having a thickness of less than 1 mm and a diameter of about 200 mm, for example, by processing this silicon wafer.

Thin Film Transistor Technology

With the thin film transistor technology, when the technology is used for the TFT-liquid crystal display apparatus, an MOS (Metal Oxide Semiconductor) type transistor, which is the switching element of the TFT-liquid crystal display device, is formed by, for example, processing an amorphous silicon film formed on a light-transmissive alkali-free glass substrate (which is amorphous and has a high strain point) or by processing the amorphous silicon film after it is melted and polycrystallized with heat from laser or the like.

Semiconductor Device

There is also a proposed technology in which a silicon film, in particular a monocrystalline silicon thin film, is formed on an insulating body with a transfer method. A semiconductor device formed with the transfer method is sometimes called SOI (Silicon on Insulator) substrate.

Semiconductor Device in Integrated Circuit

The aforementioned semiconductor device is used in the integrated circuit field to improve the performance of semiconductor elements such as transistors.

That is, when the aforementioned semiconductor device is used to make a transistor, the elements can completely be separated from each other easily. This reduces the operational restriction and provides a favorable transistor characteristics and a high performance.

Here, the substrate used in the integrated circuit field only needs to be an insulating body or an insulating film. Whether it is transparent or not, or crystalline or not does not matter.

Semiconductor Devices in Display Apparatus

On the other hand, for the TFT-liquid crystal display (LCD: Liquid Crystal Display) apparatus, the TFT-organic electroluminescence (OLED: Organic Light Emitting Diode) display apparatus, or the like, the substrate needs to be transparent because of the structure, and typically an amorphous substrate such as a glass substrate is used.

Once an amorphous silicon film or a polysilicon film is formed on the aforementioned substrate, the aforementioned TFT is formed accordingly. This TFT is used as a switching element or the like for driving the display device in a so-called active matrix manner.

Further, for integration on a substrate of peripheral drivers, timing controller, and the like that are used for driving the active matrix, studies have been conducted to make a higher performance substrate having a silicon film formed thereon.

Polysilicon Film

That is, conventionally, when a polysilicon film was used as the silicon film, localized levels in the gap due to the imperfect crystallinity and localized levels in the gap due to the defects around the crystal grain boundary were often found. The presence of such localized levels caused a lower mobility and an increased sub-threshold coefficient (S coefficient) among other things, which lowered the performance of the transistor.

Also, if the crystallinity of the polysilicon film is imperfect in the thin film transistor, localized levels and fixed charges tend to be formed in the interface between the silicon film and the gate insulating film. The formation of these fixed charges made it difficult to control the thin film transistor threshold voltage and to obtain a desired threshold voltage.

In the case of polysilicon films on a large glass substrate, in particular, it is difficult to integrate to a high degree the devices formed such as transistors. Consequently, improvement in the performance and operating speed of the devices was also difficult.

In the case of a polysilicon film obtained by irradiating an amorphous silicon film with laser light for heating, the mobility and threshold voltage of the transistors formed varied significantly. This is because the grain size of the polysilicon film obtained is non-uniform due to the presence of the crystal grain boundary of the polycrystalline Si and the fluctuation in the radiation energy of the laser applied.

Monocrystalline

In order to solve the aforementioned problems that occur when a polysilicon film is used, devices that use the monocrystalline silicon are being investigated.
Patent Document 1:
Patent Document 1 below discloses an example of the device that uses monocrystalline silicon.

That is, the Patent Document 1 below describes a semiconductor device in which a monocrystalline silicon thin film is provided on the coating film formed on a glass substrate serving as the insulating substrate of the semiconductor devices. In the semiconductor device, the monocrystalline silicon thin film becomes an isolated layer due to the implantation of hydrogen ions into monocrystalline silicon substrate.

### RELATED ART DOCUMENTS

### Patent Documents

Patent Document 1: Japanese Patent Application Laid-Open Publication No. 2004-134675 (publication date: Apr. 30, 2004)
Patent Document 2: U.S. Pat. No. 7,176,528 (issue date: Feb. 13, 2007)
Patent Document 3: Japanese Patent Application Laid-Open Publication No. 2006-518116 (Publication date: Aug. 3, 2006)

### SUMMARY OF THE INVENTION

### Problems to be Solved by the Invention

Air Bubbles

However, in the conventional semiconductor device, air bubbles can be generated between the glass substrate and the monocrystalline silicon thin film.

Here, the air bubbles between the glass substrate and the monocrystalline silicon thin film refer to fine air bubbles generated between the glass substrate and the monocrystalline silicon thin film, and at such locations, the monocrystalline silicon thin film is “floating” from the glass substrate, i.e., the monocrystalline silicon thin film is not in contact with the glass substrate. This is further explained below.

Structure of the Semiconductor Device

First, the general structure and manufacturing method of a semiconductor device is described with reference to FIG. 9(a) to FIG. 9(e). Here, FIG. 9(a) to FIG. 9(e) are cross-sectional views schematically illustrating the manufacturing process of a semiconductor device.

As shown in FIG. 9(e), which is a cross-sectional view schematically illustrating the structure of a semiconductor device, the semiconductor device 10 is composed of an insulating substrate for semiconductor device, such as a glass substrate 20, with a monocrystalline silicon thin film 90 provided thereon.

Method for Manufacturing the Semiconductor Device

The semiconductor device 10 is manufactured as described below.

First, an insulating substrate for semiconductor device, such as the glass substrate 20, and a monocrystalline silicon substrate 60 are prepared (see FIG. 9(a) and FIG. 9(b)). On the surface of the monocrystalline silicon substrate 60, a silicon dioxide (SiO₂) film 61 is provided.

Ion Implantation

Next, as shown in FIG. 9(c), a separating material is implanted into the monocrystalline silicon substrate 60. Specifically, hydrogen ions, as the separating material, are implanted into the almost entirety of the hydrogen ion implantation side surface 62, which is one side of the monocrystalline silicon substrate 60 (see the arrows in FIG. 9(c)).

Once the hydrogen ions are implanted, the hydrogen ions proceed into the hydrogen ion implantation side surface 62 to a certain depth of the monocrystalline silicon substrate 60 and remain there. As a result, a hydrogen ion implantation region 66 having a distribution peak is formed.

The hydrogen ions implanted form a concentration distribution profile in the direction of the depth of the monocrystalline silicon substrate 60, and the region around the concentration peak becomes a separation interface 68, which is described later.

Bonding

Next, as shown in FIG. 9(d), the glass substrate 20 shown in FIG. 9(a) and the monocrystalline silicon substrate 60 shown in FIG. 9(c) are bonded together. When they are bonded, the hydrogen ion implantation side surface 62 of the monocrystalline silicon substrate 60 must contact the glass substrate 20. That is, the hydrogen ion implantation side surface 62 of the monocrystalline silicon substrate 60 becomes the transferring surface 70 from which the transfer to the receiving surface 22 of the glass substrate 20 takes place.

Cleavage Separation

Next, the monocrystalline silicon substrate 60 is separated along the cleavage to form a monocrystalline silicon thin film 90 on the glass substrate 20.

Specifically, at 600 degrees, for example, the glass substrate 20 to which the monocrystalline silicon substrate 60 is bonded is heated. The heating, as shown in FIG. 9(e), separates the monocrystalline silicon substrate 60 into a monocrystalline silicon substrate main body 72 and a monocrystalline silicon thin film 90 along the separation interface 68. Then, a portion of the semiconductor device 10, which is the glass substrate 20 with the monocrystalline silicon thin film 90 provided thereon, is formed.

Device Transfer

Although in the description above, by bonding the monocrystalline silicon substrate 60 to the glass substrate 20, a semiconductor device 10, which is the glass substrate 20 with the monocrystalline silicon thin film 90 provided thereon, is obtained. However, instead of the monocrystalline silicon substrate 60, a semiconductor substrate on which devices and the like are already formed can also be bonded in a similar process.

Air Bubbles

The semiconductor device 10 formed in the manner described above has a problem. That is, air bubbles 94 are generated in the interface 92 between the monocrystalline silicon thin film 90 and the glass substrate 20, for example.

That is, as shown in FIG. 10, which is a cross-sectional view of the semiconductor device 10, the air bubble 94 is generated in the interface 92 between the monocrystalline silicon thin film 90 and the glass substrate 20. In that area, the monocrystalline silicon thin film 90 transferred to the glass substrate 20 is lifted above the glass substrate 20.

Cause of Air Bubble Generation

There are many possible causes of the generation of air bubbles 94.

In most cases, air bubbles are generated during the heating process in which the monocrystalline silicon substrate 60 bonded to the glass substrate 20 is separated along the separation interface 68, which serves as a cleavage.

That is, it is considered that the air bubbles 94 tend to be generated in the heating process conducted to separate the substrate along the separation interface 68 of the hydrogen ion implantation region 66, which is performed after the monocrystalline silicon substrate or a semiconductor substrate on which devices and the like are formed is bonded to a light-transmissive substrate. It is also considered that often the air bubbles 94 are formed in a region of the transfer interface 92 where the binding energy is low as a result of hydrogen, water, and the like contained in the monocrystalline silicon substrate, monocrystalline silicon thin film, and the like gathering in such a region.

The semiconductor device 10 in which air bubbles 94 have been generated in the transfer interface 92 cannot be used as an intended semiconductor device 10. This causes a lower production yield of the semiconductor device 10.

Patent Documents 2 and 3

Patent Documents 2 and 3 disclose methods of forming a SOI (Silicon On Insulator: semiconductor on an insulating body) structure in which a region of increased oxygen concentration and a region of reduced positive ion concentration are provided in a semiconductor layer, and voltages and temperatures are applied.

However, these methods have some drawbacks, such as the complex semiconductor layer structure and the fact that voltages and temperatures need to be applied. These add complication to the manufacturing process.

Thus, the present invention was devised to solve the problems described above, and is aiming at providing an insulating substrate for semiconductor device and a semiconductor device having a good bondability between the insulating substrate and the silicon thin film, and in which air bubbles are unlikely to be generated in the bonding interface between the insulating substrate and the silicon thin film.

### Means for Solving the Problems

In order to solve the problems discussed above, an insulating substrate for semiconductor device of the present invention is an insulating substrate for semiconductor device that is capable of constituting a semiconductor device when a silicon film is provided on the surface through a transfer, and is made of an insulating material, wherein the surface has a receiving surface on which the silicon film can be provided, the receiving surface has a wavy structure with ripples, and the height of the ripple having a period of 200 to 500 microns does not exceed 0.40 nm.

The insulating substrate for semiconductor device of the present invention may have a wavy structure with a height of the ripples not exceeding 0.35 nm.

According to the configuration above, the height of the ripples of the insulating substrate having a period of 200 to 500 microns, that is, the midrange roughness, does not exceed 0.40 nm, and more preferably does not exceed 0.35 nm.

As a result, generation of air bubbles, which tends to occur when the midrange roughness exceeds 0.40 nm, is suppressed.

This is because the self-bonding of the silicon film to an insulating substrate such as a glass substrate tends to occur when the midrange roughness is no more than 0.40 nm, preferably no more than 0.35 nm. Because the self-bonding between the insulating substrate and the silicon film is likely to occur, air bubbles are unlikely to be generated in the bonding interface between the insulating substrate and the silicon film.

Consequently, the configuration described above can provide an insulating substrate for semiconductor device having a good bondability between the insulating substrate and the silicon film and a great binding energy between the insulating substrate and the silicon film, in which air bubbles are unlikely to be generated in the bonding interface.

### Effects of the Invention

An insulating substrate for semiconductor device according to the present invention has, as described above, a receiving surface on which a silicon film can be provided, the receiving surface has a wavy structure with ripples, and a height of the ripples having a period of 200 to 500 does not exceed 0.40 nm.

Consequently, an insulating substrate for semiconductor device that can be provided has a good bondability between the insulating substrate and the silicon thin film, in which air bubbles are unlikely to be generated in the bonding interface between the insulating substrate and the silicon thin film.

### BRIEF DESCRIPTION OF THE DRAWINGS

FIG. 1 shows an embodiment of the present invention, schematically illustrating a method for manufacturing a semiconductor device.

FIG. 2 shows an embodiment of the present invention, schematically illustrating a method for manufacturing a semiconductor device.

FIG. 3 shows the relationship of the microroughness of the glass substrate to the bondability and binding energy.

FIG. 4 shows the relationship of the midrange roughness of the glass substrate to the bondability and binding energy.

FIG. 5 schematically shows the roughness of a glass substrate.

FIG. 6 schematically shows the roughness of a glass substrate.

FIG. 7 shows another embodiment of the present invention, schematically illustrating the structure of a semiconductor device.

FIG. 8 shows another embodiment of the present invention, illustrating cross-sectional views of a semiconductor device in respective manufacturing processes.

FIG. 9 is a cross-sectional view of the semiconductor device in respective manufacturing processes.

FIG. 10 is a cross-sectional view of the semiconductor device, illustrating the air bubble generation in the semiconductor device.

### DETAILED DESCRIPTION OF EMBODIMENTS

Below, embodiments of the present invention are described.

### Embodiment 1

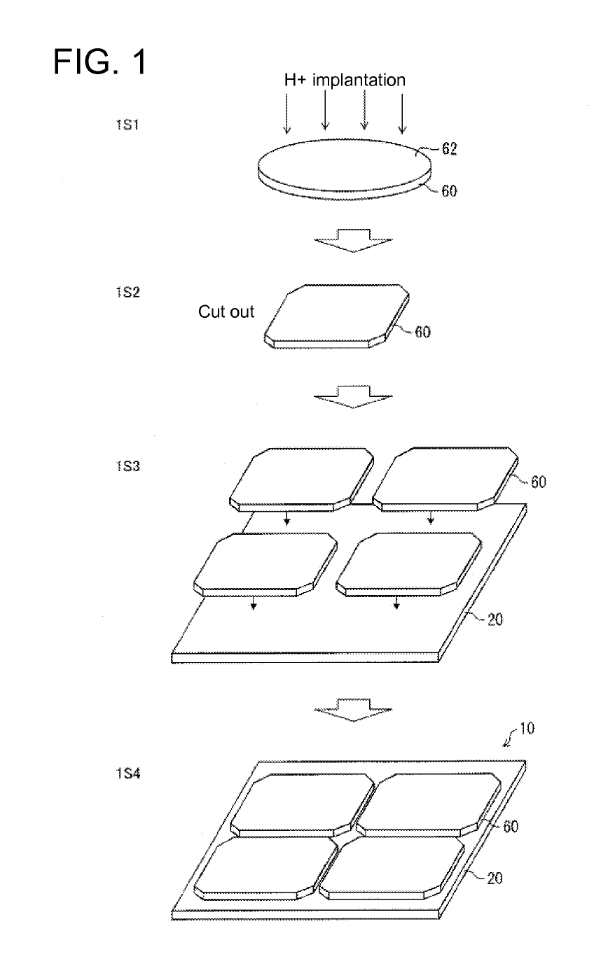

First, a semiconductor device 10 of the present embodiment, and a method of manufacturing the semiconductor device 10 are schematically described with reference to FIG. 1.

FIG. 1 schematically shows the method of manufacturing the semiconductor device 10 of the present embodiment.

Monocrystalline Silicon Substrate

First, a monocrystalline silicon substrate 60 with a silicon dioxide film formed thereon is prepared by oxidizing the surface or providing a silicon dioxide (SiO₂) film over the surface of the monocrystalline silicon substrate 60 with the CVD (Chemical Vapor Deposition) or a like method.

Next, as shown in step 1 of FIG. 1 (1S1), hydrogen ions (H+) of a prescribed concentration are implanted into the monocrystalline silicon substrate 60 with a prescribed energy.

Then, as shown in step 2 of FIG. 1 (1S2), the monocrystalline silicon substrate 60 is cut into a prescribed shape.

Glass Substrate

A glass substrate 20 as an insulating substrate is prepared. In the preparation, the roughness (midrange roughness) of the glass substrate 20 is set to 0.1 to 0.33 nm over a range of several hundred microns. The surface of the glass substrate 20 is then activated.

Here, for the glass substrate 20, #(code) 1737 (product name), which is Corning's alkali earth—aluminoborosilicate glass, for example, can be used as is.

Another example of the glass substrate 20 is a glass substrate over whose entire surface a thin silicon dioxide film is deposited by plasma CVD and also an amorphous silicon (Si) film having a thickness of 50 to 100 nm, for example, is deposited. In that case, the silicon dioxide film and the amorphous silicon film in prescribed regions are removed.

The amorphous silicon film can also be crystallized by laser radiation, solid-phase growth, or the like.

SC1 Solution

Also, for the purpose of washing and activating the surface of the glass substrate 20, SC1 solution can be sprayed on the glass substrate 20 (SC1 solution shower) or the glass substrate 20 can be submerged in the SC1 solution.

Here, the SC1 solution is prepared by mixing the commercially available ammonia solution (NH₄OH: 30%), hydrogen peroxide solution (H₂O₂: 30%), and pure water (H₂O). These solutions are mixed by the ratio of 5:12:60, for example, for use.

Oxidized Silicon Film

As described above, a thin silicon dioxide film may be deposited over the surface of the glass substrate 20. Also, the silicon dioxide film is preferably deposited by plasma CVD using TEOS (Tetraethyl Orthosilicate) oxygen mixed gas.

By depositing the silicon dioxide film, the damage to the surface of the glass substrate 20, which is caused by the treatment with SC1 solution, is reduced.

On the other hand, however, by depositing a silicon dioxide film by CVD, the flatness of the glass substrate 20 surface is compromised.

These counteracting aspects were studied, and it was found that in the case of the glass substrate 20 manufactured in the fusion method, overall, the glass substrate 20 without a silicon dioxide film deposited on the surface demonstrates higher bondability with the monocrystalline silicon substrate.

When a silicon dioxide film is provided as the oxide film, the film thickness preferably does not exceed several tens of nanometers, and specifically 30 nm. When the oxide film is provided, the film thickness is preferably at least 5 nm.

The silicon dioxide film as the oxide film does not necessarily have to be provided.

Bonding

Next, as shown in step 3 of FIG. 1 (1S3) and step 4 of FIG. 1 (1S4), the hydrogen ion implantation side surface 62 of the monocrystalline silicon substrate 60 is firmly attached to the glass substrate 20 for bonding.

Cleavage Separation

Then, after about an hour of heat treatment at approx. 250 degrees, a fast heat treatment for about 5 minutes at 600 degrees is conducted to separate the monocrystalline silicon substrate 60 along the separation interface 68 in the hydrogen ion implantation region 66.

Here, the hydrogen ion implantation region 66 refers to a region in the monocrystalline silicon substrate 60, where, due to the hydrogen ion implantation described above, the hydrogen ions are distributed to a prescribed concentration.

Next, the surface of the monocrystalline silicon that remains on the glass substrate 20 after the cleavage separation is etched away in the amount of approx. 200 nm through dry-etching and TMAH (Tetramethylammonium hydroxide: N(CH₃)₄OH), which is used to remove any damage made during the dry-etching. As a result, a monocrystalline silicon thin film, which is a silicon film having a thickness of about 50 nm, is obtained on the glass substrate 20.

Then, ramp annealing is conducted for one minute at approx. 800 degrees, and unnecessary monocrystalline silicon thin film is removed by etching to leave island-shaped portions that will be active regions of the device.

Next, a silicon dioxide film having a thickness of approx. 100 nm is deposited, and then this silicon dioxide film is etched back by approx. 120 nm with RIE (Reactive Ion Etching).

Next, as a gate oxide film, an oxide film having a thickness of approx. 20 nm is formed by plasma CVD using a mixed gas of silane (SiH₄) and dinitrogen monoxide (N₂O).

Then, through a process similar to the general polysilicon TFT formation process, a gate electrode is formed and N+ and P+ are implanted. A silicon dioxide first interlayer insulating film, contact holes, metal (AlSi) wiring, interlayer insulating film made of silicon nitride (SiNx) and silicon dioxide, via holes, transparent electrodes are then formed sequentially to constitute a monocrystalline silicon integrated circuit or a pixel array TFT (Thin Film Transistor) of liquid crystal display apparatus or the like.

Manufacturing Process in Detail

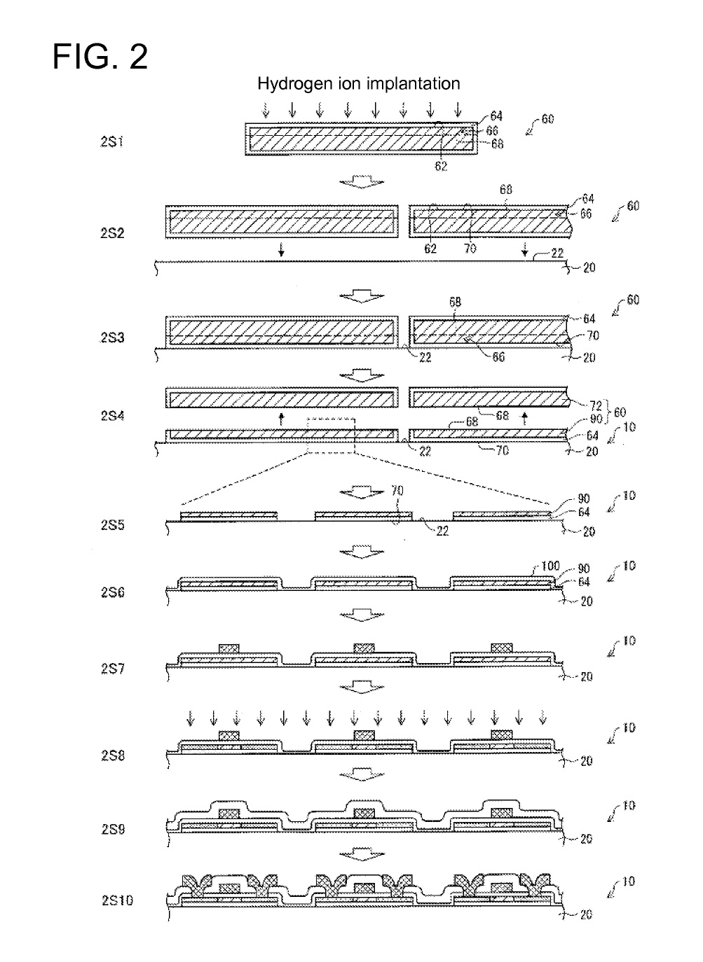

Below, the respective configurations are described in more detail with reference to FIG. 2.

FIG. 2 schematically shows a method for manufacturing a semiconductor device according to the present embodiment.

Glass Substrate

First, a glass substrate 20 as the insulating substrate is prepared. The glass substrate 20 has a roughness value of 0.1 to 0.33 nm over a range of several hundred microns, and the surface is treated for activation with a solution containing hydrogen peroxide solution, such as SC1.

Here, as the glass substrate 20, #1737 (product name) by Corning, which is an alkali earth—aluminoborosilicate glass, for example, can be used as is.

SC1 Washing

Also, the glass substrate 20 was subjected to SC1 solution shower or was submerged in SC1 solution for cleaning and surface activation.

The glass substrate 20 is not limited to those discussed above. As described above, the glass substrate 20 may have a silicon dioxide film or amorphous silicon film deposited on the surface, for example.

2S1

On the other hand, the monocrystalline silicon substrate 60 is prepared as described below.

Silicon Dioxide Film

First, a silicon dioxide film 64 is formed on the surface of the monocrystalline silicon substrate 60. The silicon dioxide film 64 can be formed by oxidization, CDV or the like.

Hydrogen Ion Implantation

Next, hydrogen ions (H+) are implanted into the monocrystalline silicon substrate 60 from the hydrogen ion implantation side surface 62 with a prescribed concentration and energy. Thus, monocrystalline silicon substrate 60 (wafer) prior to the transfer onto the glass substrate 20 is ready.

In the present embodiment, a 200 nm-thick silicon dioxide film 64 was formed on the surface of the monocrystalline silicon substrate 60 by thermal oxidation.

Then, 5×10¹⁶ hydrogen ions/cm² were implanted into the monocrystalline silicon substrate 60 from the hydrogen ion implantation side surface 62 with a prescribed energy.

After the ion implantation described above, the hydrogen ions implanted proceeds from the hydrogen ion implantation side surface 62 into a certain depth inside the monocrystalline silicon substrate 60, and remain there to form a hydrogen ion implantation region 66.

The hydrogen ions implanted form a concentration distribution profile in the direction of the depth of the monocrystalline silicon substrate 60, and the region around the concentration peak becomes a separation interface 68, which is described later.

Division

Next, the monocrystalline silicon substrate 60 is divided into smaller pieces, which are cut into a prescribed shape.

In the present embodiment, the small pieces of the monocrystalline silicon substrate 60 are cut out of a 200 mm wafer in square shapes having sides of approx. 151 mm each (with four corners cut off by approx. 7 mm).

2S2 and 2S3

SC1 Washing

The small pieces of the monocrystalline silicon substrate 60 are bonded to the glass substrate 20. Prior to the bonding, the pieces of the monocrystalline silicon substrate 60 were washed with SC1.

Bonding

The four small pieces are bonded to the glass substrate 20 such that the hydrogen ion implantation side surface 62 firmly attaches to the surface of the glass substrate 20. That is, the pieces are bonded to the glass substrate 20 such that the hydrogen ion implantation side surface 62 of the monocrystalline silicon substrate 60, which is the transferring surface 70, faces the receiving surface 22 of the glass substrate 20.

2S4

Heat Treatment

Next, the glass substrate 20 and the monocrystalline silicon substrate 60, which are bonded together, are subjected to a heat treatment at approx. 250 degrees. Then, a fast heat treatment is conducted for about 5 minutes at 600 degrees to separate the monocrystalline silicon substrate 60 along the separation interface 68.

Through this cleavage separation, the monocrystalline silicon substrate 60 separates into a monocrystalline silicon substrate main body 72 and a monocrystalline silicon thin film 90 along the separation interface 68. Then, the monocrystalline silicon thin film 90 remains on the glass substrate 20.

Dry Etching

Next, the surface of the monocrystalline silicon thin film 90 on the glass substrate 20 was etched by dry-etching and TMAH in the amount of about 200 nm to obtain a 50 nm-thick monocrystalline silicon thin film 90 on the glass substrate 20.

Over the surface of the glass substrate 20, a thin silicon dioxide film may be deposited. Also, the silicon dioxide film is preferably deposited by plasma CVD using TEOS oxygen mixed gas.

As described earlier, with the deposition of the silicon dioxide, the damage resulted to the glass substrate surface from the SC1 treatment is reduced. On the other hand, the surface flatness is compromised by depositing the silicon dioxide by CVD. This counteracting aspects were studied, and it was found that in the case of a glass substrate 20 manufactured by the fusion method, the highest overall bondability is obtained when a silicon dioxide film is not deposited on the surface of the glass substrate 20.

2S5

Next, the monocrystalline silicon thin film 90 and the glass substrate 20 were subjected to ramp annealing for 15 seconds at 800 degrees. With this process, unnecessary monocrystalline silicon thin film 90 was etched away, leaving island-shaped portions that will be active regions of the device.

2S6

Next, over the remaining monocrystalline silicon thin film 90, a silicon dioxide film 100 having a thickness of about 100 nm was deposited, which was then etched back by approx. 120 nm by RIE.

Next, as a gate oxide film, an oxide film having a thickness of approx. 60 nm was formed with plasma CVD, using a mixed gas of silane and dinitrogen monoxide.

For the rest of the process, a process similar to the usual and well-known polysilicon TFT formation process can be used.

Although detailed explanation is omitted, as shown in FIG. 2, a gate electrode was formed, N+ and P+ are implanted, and silicon dioxide first interlayer film, contact holes, and metal (AlSi) wirings are formed. Then, although further processes are not shown in the figure, a second interlayer insulating film made of a silicon nitride film and silicon dioxide, via holes, and a transparent electrode were sequentially formed.

Microroughness of Glass Substrate

Next, the glass substrate 20 of the semiconductor device 10 of the present embodiment is described.

Specifically, the relationship of the microroughness (short-distance roughness) and midrange roughness (middle distance roughness) of the glass substrate to the bondability and binding energy between the glass substrate and the monocrystalline silicon substrate is explained.

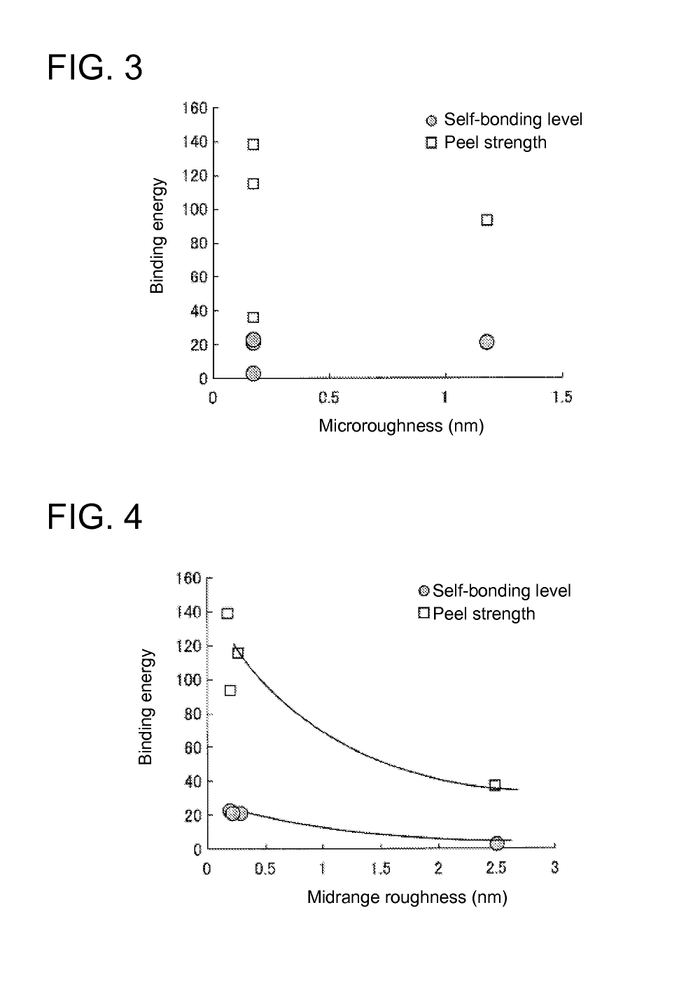

FIG. 3 shows the relationship of the microroughness of the glass substrate to the bondability and binding energy.

That is, the horizontal axis of the graph shown in FIG. 3 represents the microroughness (Ra) (nm), and the vertical axis represents the binding energy (mJ/m²).

In FIG. 3, dark circles and white squares represent the bondability between the glass substrate and the monocrystalline silicon substrate. That is, the dark circles of FIG. 3 represent the self-bonding level (gap closing) as a result of attaching the monocrystalline silicon substrate to the glass substrate, and white squares represent the peel strength needed to separate the glass substrate and the monocrystalline silicon substrate from each other after they were bonded together.

The microroughness refers to the arithmetic average roughness (Ra: JIS B0601) over a short distance, specifically over a range (region) of about a few 10 microns (more specifically, 10 to 30 microns, for example).

Ra, the microroughness, was evaluated using an AFM (Atomic Force Microscope). Specifically, Dimension V Scaning Probe Microscope by Vecco Instruments Inc. was used to evaluate the microroughness.

FIG. 3 shows the bondability (self-bonding level) and binding energy (peel strength) when a monocrystalline silicon substrate cut out from a wafer into a prescribed shape is firmly attached and bonded to various glass substrates having an Ra of 0.15 to 0.25 nm.

For the bonding, the hydrogen ion implantation side surface of the monocrystalline silicon substrate and the glass substrate were washed with SC1.

As shown in FIG. 3, for the same microroughness of the glass substrate, the bondability between the glass substrate and the monocrystalline silicon substrate can vary significantly. Likewise, for the same microroughness, the binding energy between the glass substrate and the monocrystalline silicon substrate can vary significantly.

This indicates that there is no correlation between the microroughness of the glass substrate, and the bondability and the binding energy of the glass substrate and the monocrystalline silicon substrate.

Detailed studies on the peel strength between the monocrystalline silicon substrate and the glass substrate which are connected by the hydrophilic direct bonding revealed that there is a strong correlation between the glass substrate type (the manufacturer or the method of manufacturing, i.e., the float method or the fusion method) and the binding energy. However, contrary to a conventional belief, no correlation was found between the microroughness of the glass substrate and the binding energy. That is, even with a glass substrates of different type or with a different binding energy, no significant difference was found in the microroughness of the glass substrate surface.

Midrange Roughness of Glass Substrate

Next, the relationship of the midrange roughness (middle distance roughness) of the glass substrate to the bondability and binding energy between the glass substrate and the monocrystalline silicon substrate is described.

FIG. 4 illustrates the relationship of the midrange roughness of the glass substrate to the bondability and binding energy.

In FIG. 4, like in FIG. 3, the horizontal axis of the graph represents the midrange roughness (Ra) (nm), and the vertical axis represents the binding energy.

Also, like in FIG. 3, the dark circles in FIG. 4 represent the degree of spontaneous bonding (self-bonding level), i.e., gap closing, as a result of attaching the monocrystalline silicon substrate to the glass substrate, and white squares represent the peel strength needed to separate the glass substrate and the monocrystalline silicon substrate from each other after they were bonded together.

The midrange roughness refers to the height of the concave and convex portions (ripples) over a range (region) of several hundred microns (specifically 200 to 500 microns, for example).

Also, unlike the microroughness measurement, the midrange roughness was measured not by AFM, but by an optical roughness measurement device. Specifically, an optical interferotype profilometer device by Ryoka Systems Inc. (Product name: RBX 3300H Lite) was used to optically measure the midrange roughness.

As shown in FIG. 4, a strong correlation was found between the microroughness of the glass substrate and the bondability and binding energy between the glass substrate and the monocrystalline silicon substrate.

That is, the midrange roughness over a range of several hundred microns, which is very difficult to measure with AFM but possible to measure with an optical measurement device, was found to have a strong correlation with the bondability and binding energy.

That is, as the midrange roughness becomes smaller, the bondability and the binding energy increase. Conversely, as the midrange roughness becomes, greater, the bondability and binding energy decrease.

Further, a detailed analysis was conducted to investigate the relationship between the midrange roughness and the glass substrate, in particular the method of manufacturing the glass substrate.

From the analysis, it was found that the surface of the glass substrate manufactured by a conventional float method has ripples over a range of several hundred microns. Glass substrates manufactured with the method discussed above are generally lightly polished to prevent a tin contamination.

On the other hand, although the surface of the glass substrate manufactured with the fusion method has almost the same microroughness as the glass substrate manufactured in the float method, the glass substrate manufactured with the fusion method demonstrated smaller midrange roughness than the glass substrate manufactured with the float method.

It is considered that the difference in the bondability and the binding energy between the glass substrate and the monocrystalline silicon substrate originates from the difference in the midrange roughness.

Cross-Sectional View of Glass Substrate

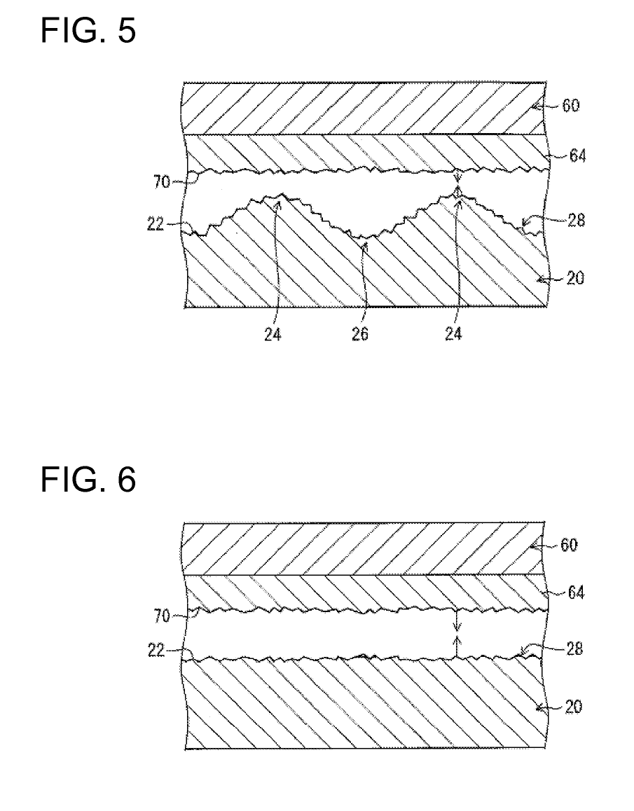

FIG. 5 and FIG. 6 schematically show the midrange roughness, magnified in the vertical directional view. FIG. 5 shows a case in which the midrange roughness is large, and FIG. 6 shows a case in which the midrange roughness is small.

A receiving surface 22 of a glass substrate 20 shown in FIG. 5 includes a midrange roughness. That is, the receiving surface 22 includes a midrange roughness convex portion 24 and a midrange roughness concave portion 26, which constitute the midrange roughness (ripples).

On the other hand, on the receiving surface 22 of the glass substrate 20 shown in FIG. 6, the midrange roughness is not formed. That is, for the glass substrate 20 shown in FIG. 6, the roughness value over a range of several hundred microns is suppressed to 0.1 to 0.33 nm.

Also, both the receiving surface 22 of the glass substrate 2 shown in FIG. 5 and the receiving surface 22 of the glass substrate 20 shown in FIG. 6 include microroughness 28 of the similar level, over a range of several 10 nm.

Regarding the glass substrate 20 shown in FIG. 5 and the glass substrate 20 shown in FIG. 6, formation of air bubbles 94 in the interface 92 interposed between the glass substrate 20 and the monocrystalline silicon thin film 90 is described.

In the interface 92 of the glass substrate 20 of FIG. 5, where a midrange roughness is present, several tens to several hundreds of air bubbles 94 were generated per square centimeter.

On the other hand, referring to the glass substrate 20 of FIG. 6 where the midrange roughness was suppressed, the amount of air bubbles 94 generated in the interface 92 was zero to no more than several bubbles per square centimeter.

Thus, generation of air bubbles 94 in the interface 92 interposed between the glass substrate 20 and the monocrystalline silicon thin film 90 was significantly suppressed by reducing the midrange roughness of the glass substrate 20 to or below 0.40 nm, or, more preferably, to or below 0.35 nm (0.1-0.33 nm).

Regarding the method of manufacturing the glass substrate, the fusion method is preferable because smaller midrange roughness can be obtained with the fusion method.

However, the glass substrate shall not be limited to those manufactured with the fusion method. The glass substrate may be manufactured with the float method, for example. If the glass substrate is manufactured with the float method, the surface, in particular, the receiving surface of the glass substrate, is preferably polished to achieve a desired midrange roughness, which is a value not exceeding 0.40 nm, for example.

Although the correlation between the microroughness of the glass substrate and the bondability and binding energy is not significant, the roughness is preferably small. Specifically, for example, the arithmetic average of microroughness preferably does not exceed 0.25 nm, and more preferably, does not exceed 0.20 nm.

### Embodiment 2

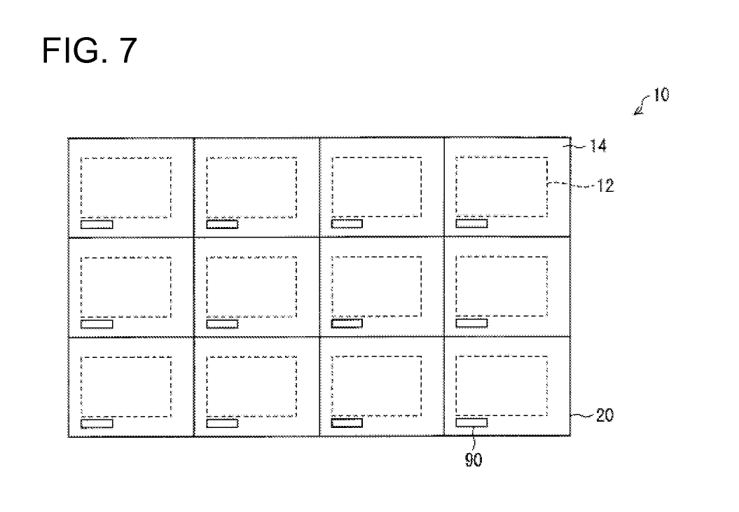

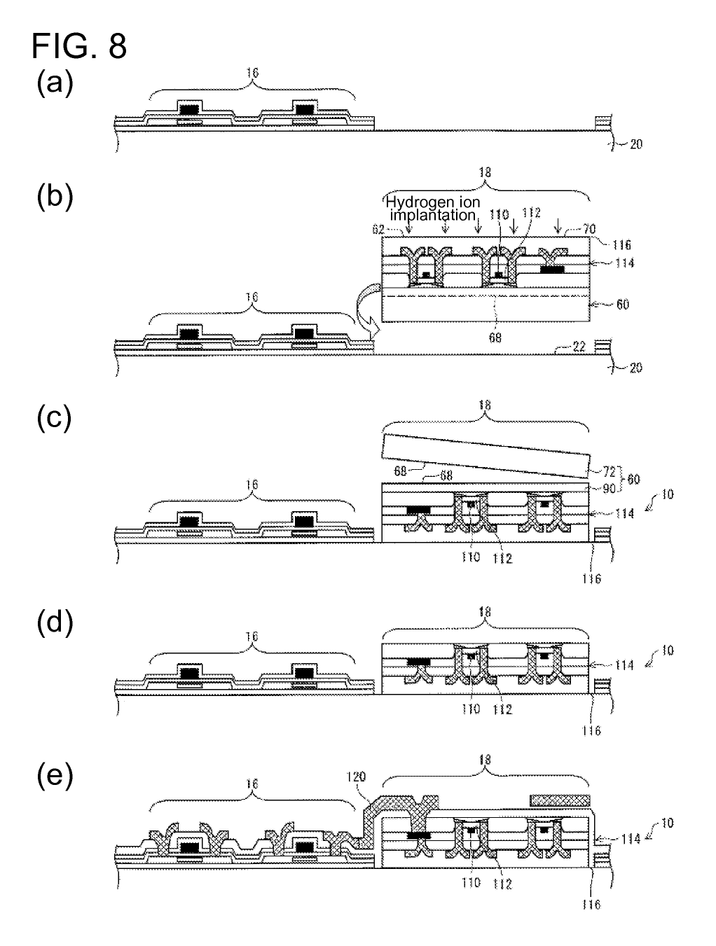

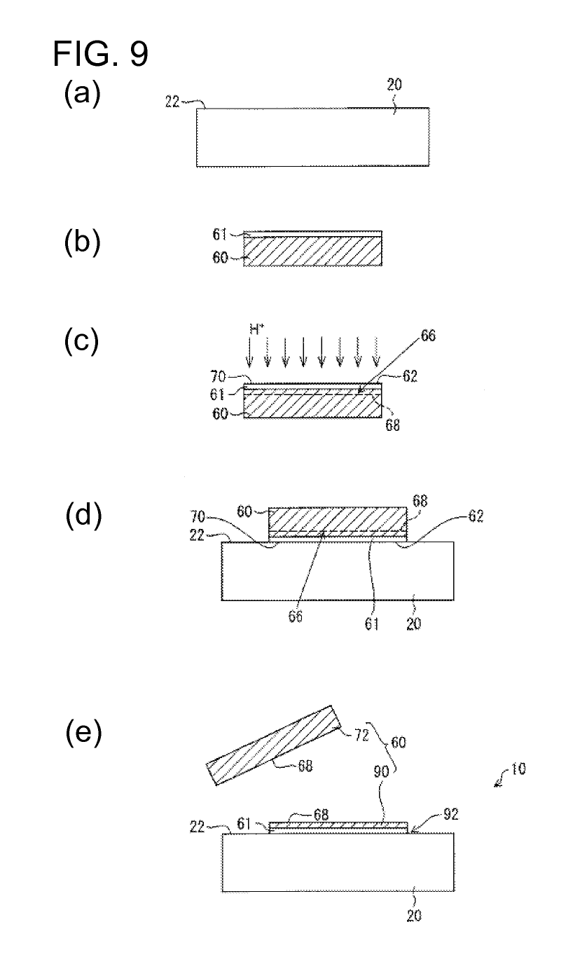

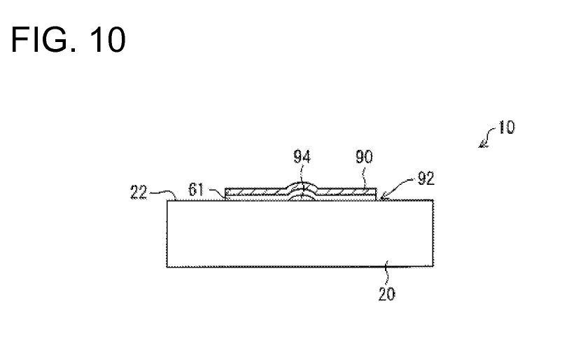

Another embodiment of the semiconductor device of the present invention is described below with reference to FIG. 7.

For simplification, same reference characters are provided for members having the same functions as those shown in the figures referenced in the description of Embodiment 1, and explanations of such members are omitted.

Referring to a semiconductor device 10 of the present embodiment, the area in which the monocrystalline silicon thin film 90 is disposed is different from that of the semiconductor device 10 of Embodiment 1.

That is, in the semiconductor device 10 of Embodiment 1, the monocrystalline silicon thin film 90 was disposed to cover almost the entire glass substrate 20.

On the other hand, in the semiconductor device 10 of the present embodiment, the monocrystalline silicon thin film 90 is disposed partially on the glass substrate 20.

Below, the semiconductor device 10 of the present embodiment is described with reference to FIG. 7, which schematically shows the configuration of the semiconductor device 10.

First, like in Embodiment 1, a monocrystalline silicon substrate 60 is transferred to the glass substrate 20 to form a monocrystalline silicon thin film 90 on the glass substrate 20.

Then, the monocrystalline silicon thin film 90 is etched away except for the portions that will become devices, which are left in island shapes. At this time, etching is conducted such that the edges of the islands are tapered off.

Depending on the required processing precision of the device and cost restriction, instead of conducting the etching so that the edges of the islands are tapered off, the edges of the islands may be etched vertically. In this case, an oxide film is then deposited and etched back with RIE, for example, to form side walls.

Next, on the monocrystalline silicon thin film 90 on which the tapers are formed, a gate oxide film, and then an amorphous silicon are deposited. Then, the amorphous silicon is irradiated with laser light or processed in a similar way for polycrystallization. As a result, TFTs in which the monocrystalline silicon and the polycrystalline silicon serve as their respective active layers are formed. These processes can be the processes generally conducted.

Large Glass Substrate

A large glass substrate 20 can be handled by forming a monocrystalline silicon thin film 90 only over a portion of the glass substrate 20. This is explained below.

According to the configuration described above, the monocrystalline silicon thin film 90 may be formed only for portions that require high-performance circuits.

For portions that are large but not required to perform complex operations such as pixel arrays, non-monocrystalline silicon such as polycrystalline silicon or amorphous silicon can be formed.

For the semiconductor device 10 shown in FIG. 7 as an example, monocrystalline silicon thin film 90 is not formed in the display section 12, but formed in the non-display section 14, which is the region around the display section 12.

In the display section 12, non-monocrystalline silicon is formed.

Thus, by arranging a monocrystalline silicon thin films 90 in the manner described above, monocrystalline silicon devices and non-monocrystalline silicon devices can be formed together not only on commercially available silicon wafers (12″ or 8″), but also on so-called “fifth generation” or “sixth generation” or even larger glass substrate 20, to make it easy to constitute a liquid crystal display apparatus.

Also, like in Embodiment 1, with a glass substrate 20 whose roughness value is 0.1 to 0.33 nm over a range of several hundred microns, the number of the air bubbles 94 generated in the interface 92 interposed between the glass substrate 20 and the monocrystalline silicon thin film 90 was suppressed to or under 0.3 to several bubbles/cm².

### Embodiment 3

Below, another embodiment of the semiconductor device 10 of the present invention is described with reference to FIG. 8(a) to FIG. 8(e).

FIG. 8(a) to FIG. 8(e) are cross-sectional views of the semiconductor device 10, schematically illustrating the method for manufacturing the semiconductor device 10 of the present embodiment.

For simplification, same reference characters are provided for members having the same functions as those shown in the figures referenced in the description of Embodiment 1, and explanations of such members are omitted.

In the present embodiment, the semiconductor device 10 is used as the active matrix substrate with TFTs.

Also, the insulating substrate of the semiconductor device 10 of the present embodiment is assumed to be a glass substrate 20 that is at least larger than 6″, 8″, or 12″ silicon wafers or quartz wafers used to industrially produce MOS-type monocrystalline silicon transistor as a constituting element of the LSI (Large Scale Integration), or the like.

Specifically, the insulating substrate is assumed to be a glass substrate that is used in the production of active matrix substrates, which is normally the substrate for active matrix display panels, for example, or any other substrate that has the same size as the glass substrate and an insulating surface.

The aforementioned substrate has a monocrystalline silicon thin film formed to cover a part of the substrate. Below, respective processes are described in detail.

Glass Substrate

First, as the insulating substrate, a glass substrate 20 whose roughness value is 0.1 to 0.33 nm over a range of several hundred microns is prepared. That is, the surface of the glass substrate 20 is subjected to an activation treatment, and the substrate is made of a transparent amorphous material. Specifically, code1737 (product name) by Corning, which is an alkali earth—aluminoborosilicate glass, for example, can be used as is.

Then, the surface of the glass substrate 20 is cleaned and activated through SC1 solution shower or immersion in SC1 solution.

Instead of the aforementioned glass substrate 20, a glass substrate 20 covered with a thin, 5 to 20 nm-thick amorphous silicon dioxide film deposited over the entire surface with plasma CVD can also be used.

When the glass substrate 20 (code1737) is used as the insulating substrate, because the glass substrate 20 is light-transmissive, the semiconductor device of the present embodiment becomes suitable for, for example, a liquid crystal display apparatus. The strain point of the code1737 is about 667 degrees. The code1737 is manufactured with the fusion method.

Other Glass Substrates

A glass substrate 20 other than the code1737 can also be used.

For example, a glass substrate 20 having a midrange roughness of 0.1 to 0.33 nm such as EAGLE (product name) by Corning, which is manufactured with the fusion method, can be used. The strain point of this glass substrate 20 is different from the code1737, but its surface flatness, i.e., the roughness over a range of several hundred microns is about the same as that of the code1737.

OA-10 (product name) by Nippon Electric Glass, which is also manufactured with the fusion method, can also be used. This glass substrate 20 has about the same roughness value (0.1-0.33 nm) over a range of several hundred microns and about the same strain point as the code1737.

Also, the glass substrate 20 is not limited to a glass substrate 20 manufactured with the fusion method. A glass substrate 20 manufactured with the float method can also be used. Regarding the glass substrate 20 manufactured in the float method, the midrange roughness value is also preferably no more than 0.4 nm, and more preferably no more than 0.35 nm. Preferably, the surface of the glass substrate 20 manufactured with the float method is polished to achieve a midrange roughness within the range stated above.

The fusion method refers to a method in which, in a manufacturing process of a glass substrate, the melted glass that overflows from both sides of the crucible gathers in a clean condition, i.e., without touching the crucible, and is taken out vertically in a downward direction. The float method refers to a method in which a melted glass is poured onto melted Sn (tin), and is taken out horizontally.

Glass Substrate Surface

The glass substrate 20 described above includes, besides the exposed surface region on which a monocrystalline silicon substrate 60 will be bonded, a base insulating film and basic components of TFT having an active layer of polycrystalline silicon (active layer, gate oxide film, gate electrode, and doped region for the source and drain) formed thereon.

The exposed surface region of the glass substrate 20, which is for bonding a monocrystalline silicon substrate 60, is covered with a protective metal such as Mo, which serves as an etching stopper when the silicon film and the silicon dioxide film disposed over it is etched away.

Brief Description of Configuration

The semiconductor device 10 of the present embodiment includes, as shown in FIG. 8(e), a glass substrate 20 as the insulating substrate, and a non-monocrystalline silicon thin film device 16 and a monocrystalline silicon thin film device 18, which coexist on the glass substrate 20. More specifically, on the glass substrate 20, a silicon dioxide film as the oxide film, a MOS-type non-monocrystalline silicon thin film transistor including a non-monocrystalline silicon thin film made of polycrystalline silicon (non-monocrystalline silicon thin film device 16), a MOS-type monocrystalline silicon thin film transistor including a monocrystalline silicon thin film (monocrystalline silicon thin film device 18), and metal wirings are disposed.

Non-Monocrystalline Silicon Thin Film Device

The MOS-type non-monocrystalline silicon thin film transistor that uses a non-monocrystalline silicon thin film includes, on a silicon dioxide/silicon nitride film as the basecoat insulating film, a non-monocrystalline silicon thin film, a silicon dioxide film as the gate insulating film, and the gate electrode. The gate electrode is formed of titanium nitride, but it can also be formed of a metal such as tungsten or molybdenum, or polycrystalline silicon, silicide, or polycide.

Monocrystalline Silicon Thin Film Device

On the other hand, the MOS-type monocrystalline silicon thin film transistor that uses a monocrystalline silicon thin film 90 includes a planarizing layer having a gate electrode, a silicon dioxide film as the gate insulating film, and a monocrystalline silicon thin film 90. Here, as the material of the gate electrode, a heavily-doped polycrystalline silicon film was used.

In the semiconductor device 10 of the present embodiment, the monocrystalline silicon thin film device is not formed sequentially on the glass substrate 20. It is pre-formed on the monocrystalline silicon substrate 60, which will be transferred to the glass substrate 20. This is described below.

Monocrystalline Silicon Thin Film Transistor

A monocrystalline silicon thin film transistor as the monocrystalline silicon thin film device 18 is formed on the monocrystalline silicon substrate 60 prior to the bonding to the glass substrate 20. The monocrystalline silicon thin film transistor is planarized entirely, and hydrogen ions are implanted to a prescribed depth with a prescribed concentration.

The monocrystalline silicon thin film transistor is bonded to and transferred onto the glass substrate 20 as it carries the gate electrode, gate insulating film, and monocrystalline silicon thin film 90 on it.

After the transfer and bonding, the glass substrate 20 and the monocrystalline silicon substrate 60 are subjected to a heat treatment to have small air bubbles generated in the hydrogen ions inlet section so that the monocrystalline silicon substrate 60 is separated along the separation interface 68. Thus, a monocrystalline silicon thin film 90 is formed on the glass substrate 20.

Although the trajectory of the hydrogen ions at the gate electrode portion is slightly different from that of the other regions, cleavage separation can be done without any problem if that difference is taken into consideration in advance.

According to the manufacturing method described above, in which the gate electrode, contacts, and the first metal wiring are formed on the monocrystalline silicon substrate and impurity ions are implanted into the source, drain, and the like, fine processing is easier this way than in the case where TFTs are formed from the monocrystalline silicon thin film 90, which has been transferred to the glass substrate 20.

In particular, when separating the monocrystalline silicon substrate 60 along the cleavage using hydrogen ions, and a glass substrate 20 is used as the insulating substrate, due to the restriction on the temperature limit of the glass substrate 20, heat treatments after the transfer cannot be conducted at a high temperature. Here, boron is inactivated by hydrogen ions, but can virtually be reactivated when enough hydrogen atoms are removed through a heat treatment conducted for several hours at about 550 degrees.

Localized levels and dislocations occurred during the process can be removed through a transient annealing (RTA) in which a heat treatment is conducted at 650 degrees for at least a few minutes.

Thermal donors generated by annealing at or below 550 degrees, and the small amount of remaining boron inactivation can be compensated by adjusting the initial amount of boron implantation in consideration of the thermal donor and boron inactivation, or by implanting boron ions (ion doping) after the transfer.

Effect of Coexistence

Thus, because the semiconductor device 10 of the present embodiment has both a MOS-type non-monocrystalline silicon thin film transistor and a MOS-type monocrystalline silicon thin film transistor coexisting on a single glass substrate 20, a high-performance, multi-functioning semiconductor device 10 on which a plurality of circuits having different characteristics are integrated can be obtained. This process can provide a high-performance, multi-functioning semiconductor device 10 at a lower cost than the case in which a transistor is entirely made of monocrystalline silicon thin film on the glass substrate 20. Further, a process like this is not restricted by the wafer size, and allows formation of displays and multi-separations in a size larger than commercially available silicon wafers which are 200 mm or 300 mm across.

In the case of an active matrix substrate for liquid crystal display apparatus that includes the semiconductor device 10 of the present invention, silicon nitride (SiNx), a resin planarizing film, via holes, and transparent electrodes, for example, are further formed for the liquid crystal display. Also, as a non-monocrystalline silicon thin film device, drivers and TFTs for the display section 12 are formed.

On the other hand, monocrystalline silicon thin film devices such as timing controllers, memories, and the like are formed in the non-display section 14. This is because higher performance is required for these devices compared to TFTs for the display section 12.

The drivers may also be formed of a monocrystalline silicon thin film device. The configuration can be determined by considering the cost and performance requirement.

Summary

Thus, high-performance and multi-functioning thin film transistors can be obtained by determining the function and purpose of respective thin film transistors in consideration of the characteristics of those made of monocrystalline silicon thin film 90, and those made of non-monocrystalline silicon thin film.

Also, in the semiconductor device 10, it becomes easier to form an integrated circuit including pixel arrays in the region of non-monocrystalline silicon thin film and in the region of monocrystalline silicon thin film 90 separately, according to the required configuration and characteristics.

As a result, integrated circuits having different operating speeds, operating power voltages, and the like can be formed in respective regions. Specifically, for example, integrated circuits in which at least one of the gate length, gate insulating film thickness, power supply voltage, and logic levels is different from others can be formed in the respective regions.

Thus, devices having different characteristics can be formed in respective regions, which provides a semiconductor device 10 having highly versatile functions.

Further, in the semiconductor device 10, integrated circuits are formed in the region of non-monocrystalline silicon thin film and in the region of monocrystalline silicon thin film 90. Consequently, for the integrated circuits formed in respective regions, different process rules can be applied in different regions.

For example, when a TFT with a short channel length is formed as an integrated circuit, if the TFT is formed in the region of a monocrystalline silicon thin film 90, there is virtually no increase in variation of TFT characteristics, because the crystal grain boundary is not present in the region of the monocrystalline silicon thin film 90.

In contrast, if the TFT is formed in the region of a polycrystalline silicon film, which is an non-monocrystalline silicon thin film, the variation increases dramatically due to the influence of the crystal grain boundary.

As a result, different process rules need to be applied in the region of the monocrystalline silicon thin film and in the region of the non-monocrystalline silicon thin film.

Thus, in the manufacturing method described above, because integrated circuits are separately formed in respective regions, a suitable process rule can be applied depending on the characteristics of the integrated circuit formed in each region.

The size of a monocrystalline silicon film device formed on the semiconductor device 10 is generally determined based on the wafer size of the LSI manufacturing apparatus. However, wafer sizes generally required by an LSI manufacturing apparatus are good enough to form a high-speed DAC (electrical current buffer) or processor, for which requirements in speed, power consumption, logic speed, timing generator, and variation are demanding, and therefore a monocrystalline silicon thin film 90 needs to be used. Wafer size, therefore, is not a big issue in the configuration described above.

Manufacturing Method

Below, a method for manufacturing the semiconductor device 10 of the present embodiment is described more specifically with reference to FIG. 8(a) to FIG. 8(e).

FIG. 8(a)

In the method of manufacturing the semiconductor device 10 according to the present embodiment, a monocrystalline silicon substrate 60 having a portion that is processed into a thin film to become a monocrystalline silicon thin film transistor is formed. Also, hydrogen ions of a prescribed concentration are pre-implanted into a certain depth. The monocrystalline silicon substrate 60 is bonded to a glass substrate 20 having an insulating surface, and is heated to be separated along the separation interface 68 in the hydrogen ions implantation region 66.

When the monocrystalline silicon substrate 60 is separated along the cleavage, an monocrystalline silicon thin film 90 is formed on the glass substrate 20. This film is etched thin for element isolation. Then, a silicon dioxide film is deposited.

Specifically, first, in a general IC production line, a part of the CMOS (Complementary Metal Oxide Semiconductor) manufacturing process is conducted. That is, for an monocrystalline silicon substrate 60, a gate electrode 110 and gate insulating film 112 are formed, source and drain impurity ion implantation (BF2⁺, As⁺), channel implantation (threshold voltage control), LDD (Lightly Doped Drain) implantation, and HALO implantation (oblique ion implantation for suppressing the short channel effect) are conducted, and a protective insulating film and a planarizing film are formed. Then, a planarizing process is conducted with CMP (Chemical-Mechanical Polishing).

Here, regarding the source and drain impurity ion implantation (BF2⁺, As⁺), channel implantation (threshold voltage control), LDD implantation, and HALO implantation (oblique ion implantation for suppressing the short channel effect), the amount of boron or boron difluoride to be implanted is typically 2 to 5 times more than the optimum implantation amount to the bulk silicon for making the MOS transistor. The amount of P to be implanted is also increased by about 1 to 3×10¹⁶ cm⁻³ more than the typical implantation amount. This is because the implantation amount for the threshold voltage required in the SOI structure is different, and also because the influence of the boron inactivation by hydrogen or thermal donor needs to be offset. Implantation amount is adjusted according to the heat treatment condition, silicon film thickness, and the characteristics of the target TFT.

After the impurity implantation, the activation process, deposition of silicon dioxide as an interlayer insulating film 114, and planarization are conducted. Next, hydrogen ions are implanted with a dose of 6×10¹⁶/cm² and a prescribed energy. Then, contact holes are opened, and metal layers are deposited and patterned. Here, tungsten is used for metal wirings, and titanium nitride is used for the barrier layer. Further, over this layer, a silicon dioxide film is deposited as an oxide film 116, and then planarized. Thus, the monocrystalline silicon substrate 60 is formed into a desired structure. For the planarization process, a dummy pattern and CMP are used as necessary.

On the other hand, in the method of manufacturing the semiconductor device 10 according to the present embodiment, as shown in FIG. 8(a), a non-monocrystalline silicon thin film transistor is pre-formed on the glass substrate 20 as a non-monocrystalline silicon thin film device 16.

FIG. 8(b) and FIG. 8(c)

The monocrystalline silicon substrate 60 is divided into a prescribed size.

The glass substrate 20 to be used as a substrate having an insulating surface is one of the glass substrates industrially used for TFT-LCD, that is, a glass substrate with a high strain point and having a roughness value of 0.1 to 0.33 nm over a range of several hundred microns.

Next, both the monocrystalline silicon substrate 60 and the glass substrate 20 are hydrophilized and bonded to each other at a prescribed location. As described above, the midrange roughness of the glass substrate 20 depends on the manufacturing method of the glass substrate 20.

Specifically, as shown in FIG. 8(b), the glass substrate 20 having an insulating surface and the monocrystalline silicon substrate 60 divided into a desired shape are washed wish SC1 and activated (hydrophilized). Then, the device side surface of the monocrystalline silicon substrate 60, which is the hydrogen ion implantation side surface 62, is aligned to a prescribed location on the glass substrate 20, and firmly attached at a room temperature for bonding. This is the process of transferring the hydrogen ions implantation side surface 62 as the transferring surface 70 of the monocrystalline silicon substrate 60 to the receiving surface 22 of the glass substrate 20.

Here, the SC1 solution is prepared by mixing the commercially available ammonia water (NH₄OH: 30%), hydrogen peroxide solution (H₂O₂: 30%), and pure water (H₂O). The solution is mixed by the ratio of 5:12:60, for example. The temperature of the SC1 solution can be a room temperature up to 80° C. Washing can be performed by immersing the substrates in the SC1 solution for 5 minutes. Because the ammonia water slightly etches the surface of the glass substrate, it is not preferable to immerse the substrates in the SC1 solution for a prolonged time.

Next, the substrates are washed for 10 minutes under the running pure water (specific resistance: 10MΩcm or higher), and are fast dried with a spin dryer or the like. After washing and drying, the glass substrate 20 and the monocrystalline silicon substrate 60 are placed in contact with each other. They bond to each other by themselves with a light push.

The monocrystalline silicon substrate 60 and the glass substrate 20 are bonded to each other with Van der Waals forces and hydrogen bonding.

Next, a heat treatment is conducted for about two hours at 200 to 300 degrees. The bond is strengthened enough when part of it becomes siloxane bonding, which is strong. Then, a rapid heat treatment is performed for 3 minutes at 580 degrees. As shown in FIG. 8(c), the monocrystalline silicon substrate 60 separates along the separation interface 68.

Here, the monocrystalline silicon thin film transistor as the monocrystalline silicon thin film device 18 is bonded to the glass substrate 20 through an inorganic insulating film. As a result, compared to the conventional method where an adhesive is used for bonding, the monocrystalline silicon thin film 90 can reliably be protected from being contaminated.

Midrange Roughness and Air Bubbles

When a glass substrate 20 having a roughness value of 0 to 0.33 nm over a range of several hundred microns is used, compared to the case where a glass substrate 20 whose midrange roughness value is greater than the aforementioned value is used, the number of air bubbles generated in the interface 92 interposed between the monocrystalline silicon thin film 90 and the glass substrate 20 that are eventually obtained decreases significantly. Specifically, when the glass substrate 20 with greater midrange roughness is used, several tens to several hundreds of air bubbles 94 are generated per square centimeter in the interface 92. But when the glass substrate 20 with a midrange roughness value of 0.1 to 0.33 nm is used, the number of the air bubbles 94 decreased to 0.3 to several bubbles or less per square centimeter.

Because of the reduction in the air bubbles 94, the defect rate of the semiconductor device 10, to which the monocrystalline silicon substrate 60 was transferred, dropped dramatically.

FIG. 8(e)

Next, the monocrystalline silicon thin film 90 transferred to the glass substrate 20 is etched in the amount of about 200 nm through dry etching and TMAH.

Thus, a monocrystalline silicon thin film 90 having a thickness of about 50 nm can be obtained on the glass substrate 20.

Further, simultaneously with the etching, element isolation is conducted. That is, a heat treatment by a furnace is conducted at 560 to 650 degrees for 1 to 4 hours, and a brief annealing by RTA is performed at 650 degrees or higher for no more than 10 minutes. Then, over the entire surface, a second silicon dioxide film having a film thickness of about 300 nm is deposited using a mixed gas of silane and dinitrogen monoxide, or with plasma CVD using TEOS and oxygen. The duration of RTA depends on the heat resistance of the glass substrate 20, and is adjusted such that the glass substrate 20 deformation is within an allowable limit.

Then, as shown in FIG. 8(e), a contact hole is opened and a metal wiring 120 made of AlSi is formed in the contact hole.

Summary

As described above, in the method of manufacturing the semiconductor device 10 according to the present embodiment, a monocrystalline silicon thin film transistor as the monocrystalline silicon thin film device 18 is formed after a non-monocrystalline silicon thin film (polycrystalline silicon thin film) is formed on the glass substrate 20. Specifically, on the glass substrate 20, after a non-monocrystalline silicon thin film transistor as the non-monocrystalline silicon thin film device 16 is formed, a monocrystalline silicon thin film transistor as the monocrystalline silicon thin film device 18 is formed.

This way, the monocrystalline silicon substrate 60 can be bonded to the glass substrate 20 while the flatness of the glass substrate 20 is maintained. Here, a protective film can be formed of Mo or the like to protect the surface and maintain the flatness. Problems such as defective bonding can be prevented from occurring by removing the oxide film in the bonding region and then removing the protective film.

Because devices having different characteristics can be formed in different regions on the glass substrate 20 in the method described above, a semiconductor device 10 having a wider variety of functions can be obtained.

Further, for the semiconductor device 10, integrated circuits are formed in the region of non-monocrystalline silicon thin film and in the region of monocrystalline silicon thin film 90. As a result, region-specific process rules can be applied to the integrated circuits formed in respective regions. For example, as mentioned earlier, if the TFT has a short channel length, there is virtually no increase in variation of TFT characteristics in a region of the monocrystalline silicon thin film, because the crystal grain boundary is not present in the region. In contrast, in a region of polycrystalline silicon film, which is a region of non-monocrystalline silicon thin film, the variation increases dramatically due to the influence of the crystal grain boundary. As a result, region-specific process rule needs to be applied in respective regions. Thus, in the semiconductor device 10 according to the present embodiment, integrated circuits can be formed in regions suitable to them based on the process rules.

In the semiconductor device 10 according to the present embodiment, the metal wiring pattern of the MOS-type monocrystalline silicon thin film transistor can be formed based on a design rule that is less restrictive than that for the gate pattern.

As a result, the metal wiring or a portion of the metal wiring of the semiconductor device 10 in which a MOS-type monocrystalline silicon thin film transistor is formed can be processed simultaneously with the metal wiring on the large substrate, which reduces the costs and improves the processing capability. Further, connection to external wirings, other circuit blocks, and TFT arrays becomes easy, which reduces the decline in production yield caused by faulty connection to an external device or the like.

Thus, the method of manufacturing the semiconductor device 10 described above is characterized in that, a glass substrate 20 is used as the substrate having an insulating surface, which is industrially used for TFT-LCD and has a high strain points and a roughness value of 0.1 to 0.33 nm over a range of several hundred microns.

The glass substrate 20 and the monocrystalline silicon substrate 60 are both subjected to hydrophilization process. After that, they are bonded together to a prescribed position.

Then, the glass substrate 20, which is the final substrate having an insulating surface, and the monocrystalline silicon substrate 60, which is cut into a shape, are washed with SC1 for activation (hydrophilization). After this, the device side of the monocrystalline silicon substrate 60 is aligned to a prescribed location on the glass substrate 20, and is attached firmly at a room temperature for bonding.

Contamination

According to the above-described method of manufacturing, compared to the conventional case in which a monocrystalline silicon substrate 60 is bonded to a glass substrate 20 with an adhesive, the height of the device can be made constant, even to a microscopic level, and the monocrystalline silicon thin film 90 can reliably be protected from being contaminated.

Air Bubbles

Also, with a glass substrate whose roughness value is 0.1 to 0.33 nm over a range of several hundred microns, compared to the case where such a glass substrate is not used, generation of air bubbles in the interface interposed between the final silicon film and the glass was significantly suppressed (reduced from several tens to several hundreds/cm² to 0—a few/cm²). This dramatically lowered the defect rate of the device that is lastly transferred.

Multi-Functionality

In the semiconductor device 10 described above, because devices of different characteristics can be formed in respective regions, a semiconductor device 10 can have more versatile functions. That is, it is easy to have a region for a non-monocrystalline silicon thin film device 16 and a region for monocrystalline silicon thin film device 18 coexist on the glass substrate 20. Consequently, the semiconductor device 10 can readily have various functions.

Process Rules

In the semiconductor device 10 described above, integrated circuits can be formed separately in a region where the non-monocrystalline silicon thin film is formed and a region where the monocrystalline silicon thin film is formed. Consequently, region-specific process rule can be applied to integrated circuits formed in the respective regions. Therefore, integrated circuits can be formed according to the process rules in respective suitable regions, for example.

Design Rules

In the semiconductor device 10 according to the present embodiment, the metal wiring pattern of the MOS-type monocrystalline silicon thin film transistor can be formed based on a design rule that is less restrictive than that for the gate pattern.

As a result, the metal wiring or a portion of the metal wiring of the semiconductor device 10 in which a MOS-type monocrystalline silicon thin film transistor is formed can be processed simultaneously with the metal wiring on the large substrate, which reduces the costs and improves the processing capability. Further, connection to external wirings and TFT arrays of other circuit blocks becomes easy. As a result, the decline in production yield caused by faulty connection to an external device or the like can be reduced.

Further, a high-performance, multi-functioning, and highly integrated circuit can be made of a general silicon wafer whose size is limited. Additionally, devices including TFT arrays can be disposed on a glass substrate for LCD production, which glass substrate is at least a few times larger than silicon wafers and has much less area restriction. This makes it possible to produce an inexpensive large screen display apparatus.

The present invention is not limited to those embodiments described above. Various changes can be made within the scope defined by the appended claims. Embodiments obtainable through the combination of technologies disclosed in different embodiments described here are also within the technological scope of the present invention.

The insulating substrate for semiconductor device of the present invention is characterized in that the arithmetic average roughness of the receiving surface over the range of 10 to 30 microns does not exceed 0.25 nm.

The insulating substrate for semiconductor device of the present invention may be characterized in that the aforementioned arithmetic average roughness does not exceed 0.20 nm.

According to the configuration described above, the receiving surface of the insulating substrate has a midrange roughness that is within the desired range, and an arithmetic average roughness over the range of 10 to 30 microns, i.e., microroughness, does not exceed 0.25 nm, and more preferably, does not exceed 0.20 nm.

As a result, the bondability between the insulating substrate and the silicon film further improves, and the number of air bubbles generated in the bonding interface further decreases.

Also, the insulating substrate for semiconductor device of the present invention is characterized in that the insulating material is glass and manufactured with the fusion method.

According to the configuration above, in the hydrophilic direct bonding between the glass substrate using glass, which is the insulating material, and the silicon film, the glass substrate is manufactured with the fusion method.

The inventors found that the glass substrates made with the fusion method generally have a small midrange roughness after conducting a comparative evaluation on various glass substrates.

The self-bonding between the glass substrate and the silicon film is, therefore, more likely to occur, the bondability between the glass substrate and the silicon film can further improve, and the number of air bubbles generated in the bonding interface can further be reduced.

Also, the insulating substrate for semiconductor device of the present invention is characterized in that the insulating material is glass and manufactured with the float method.

Also, the insulating substrate for semiconductor device of the present invention is characterized in that the receiving surface is polished to obtain the above-mentioned surface ripples whose height does not exceed 0.40 nm.

In the configuration described above, in the hydrophilic direct bonding between a glass substrate using glass as the insulating material and a silicon film, the height of the ripples is no more than 0.40 nm with the glass substrate manufactured with the float method, and more preferably by polishing the receiving surface.

The self-bonding between the glass substrate and the silicon film is, therefore, more likely to occur, the bondability between the glass substrate and the silicon film can further improve, and the number of air bubbles generated in the bonding interface can further be reduced.

Also, the insulating substrate for semiconductor device of the present invention is characterized in that no oxide film is provided on the receiving surface.

According to this configuration, the flatness of the receiving surface is likely to be maintained, because no oxide film is provided on the receiving surface.

Consequently, it becomes easier to improve the bondability between the insulating substrate and the silicon film.

Also, the insulating substrate for semiconductor device of the present invention is characterized in that an oxide film is provided on the receiving surface, and the film thickness of the oxide film does not exceed 30 nm.

According to this configuration, an oxide film having a film thickness of no more than 30 nm is provided on the receiving surface.

As a result, the flatness of the receiving surface is likely to be maintained, and the receiving surface deterioration due to the processes with SC1 solution and the like can be suppressed.

As a result, it becomes easy to improve the bondability between the insulating substrate and the silicon film.

The above-mentioned oxide film preferably has a thickness of at least 30 nm.

If the oxide film is too thin, it becomes more susceptible to the influence of SC1 depending on the conditions of film deposition or the like. If the film quality is good, or under a similar condition, the film thickness can be 5 nm. However, in consideration of the case where the film quality is not good, or under a similar condition, the film thickness is preferably at least 30 nm.

On the other hand, from the perspective of the flatness, the film thickness is preferably no more than 20 nm, for example.

A semiconductor device of the present invention is characterized in that a silicon film is transferred to the insulating substrate for semiconductor device.

According to the configuration describe above, because the bondability between the insulating substrate and the silicon film is good, and because air bubbles are not likely to be generated in the bonding interface interposed between the insulating substrate and the silicon film, it becomes easy to improve the production yield of the semiconductor device.

### INDUSTRIAL APPLICABILITY

In the semiconductor device of the present invention, a semiconductor thin film can be formed by attaching it to an insulating substrate. Consequently, the semiconductor device can suitably be used for active matrix type liquid crystal displays or the like, which is required to provide high performance and high production yield.

### DESCRIPTION OF REFERENCE CHARACTERS

10 semiconductor device
20 glass substrate (insulating substrate)
22 receiving surface
24 midrange roughness convex portion
26 midrange roughness concave portion
28 microroughness
90 monocrystalline silicon thin film (silicon film)

1. An insulating substrate for semiconductor device that is made of an insulating material, and is capable of constituting a semiconductor device when a silicon film is provided on a surface of the substrate by transfer,
wherein said surface has a receiving surface onto which the silicon film can be provided, and
wherein said receiving surface has a wavy structure having ripples, and a height of the ripples having a period of 200 to 500 microns does not exceed 0.40 nm.

2. The insulating substrate for semiconductor device according to claim 1, wherein the height of said ripples does not exceed 0.35 nm.

3. The insulating substrate for semiconductor device according to claim 1, wherein an arithmetic average roughness of said receiving surface over a range of 10 to 30 microns does not exceed 0.25 nm.

4. The insulating substrate for semiconductor device according to claim 3, wherein said arithmetic average roughness does not exceed 0.20 nm.

5. The insulating substrate for semiconductor device according to claim 1, wherein said insulating material is glass and manufactured with a fusion method.

6. The insulating substrate for semiconductor device according to claim 1, wherein said insulating material is glass and manufactured with a float method.

7. The insulating substrate for semiconductor device according to claim 6, wherein said receiving surface is polished such that the height of said ripples does not exceed 0.40 nm.

8. The insulating substrate for semiconductor device according to claim 1, wherein no oxide film is provided on said receiving surface.

9. The insulating substrate for semiconductor device according to claim 1, wherein an oxide film is provided on said receiving surface, and the film thickness of said oxide film does not exceed 30 nm.

10. A semiconductor device comprising the insulating substrate for semiconductor device according to claim 1 onto which a silicon film has been transferred.
